(19) United States
(12) Patent Application Publication
(10) Pub. No.: US 2025/0234467 A1
(43) Pub. Date: Jul. 17, 2025

(54) ELECTRICAL APPLIANCE AND METHOD FOR SEPARATING AN ELECTRICAL APPLIANCE

(71) Applicant: Siemens Aktiengesellschaft, München (DE)

(72) Inventors: Matthias Strobl, Hohenkemnath (DE); Ekkehard Plechinger, Röckersbühl (DE); Jürgen Reisinger, Schmidgaden (DE); Martin Amann, Abensberg/Pullach (DE)

(21) Appl. No.: 18/854,640

(22) PCT Filed: Apr. 7, 2022
(86) PCT No.: PCT/EP2022/059306

§ 371 Date: Oct. 7, 2024

(51) Int. Cl. H05K 5/02; B09B 5/00

(52) U.S. Cl. CPC H05K 5/0252; B09B 5/00

(57) ABSTRACT

An electrical appliance includes electronic components which are enclosed by a housing. A marking or label relating to a disassembly of the electrical appliance is applied to the housing. In the process of disassembling the appliance, disassembly instructions are obtained from a database and the device is disassembled and sorted.

The invention relates to an electrical device and to a method for disassembling an electrical device.

The efficient use of resources is one of the key challenges faced by our company. All manufacturers of products, such as electrical devices for example, are therefore encouraged to develop strategies and methods for making products more sustainable. One approach to this is increasing the recycling rate of the products, such as electrical devices for example, by separation yielding unmixed recyclable material as far as possible after the end of the service life or, if possible, enabling components to be reused.

Product development is a process involving a large number of complex challenges and requirements. Innovations have to be developed under considerable time and cost pressure. At present, the focus here is on optimization of function and costs. The “design for disassembly” is an additional requirement for which little space has been provided in the current product development process up to now. This leads to typical products often being very difficult or even impossible to break down after the end of the service life and separation yielding unmixed parts being so complicated that it is dispensed with for economic or technological reasons.

Shredding after the end of the service life is the method for disassembly of products most commonly used in Germany at present. After the shredding, the fragments are subjected to multistage sorting methods. These sorting methods are very complicated. As soon as the products have been shredded, separation yielding unmixed parts is difficult to technically no longer possible to implement.

Valuable components, such as permanent magnets for example, are destroyed during shredding. The shredding releases toxic substances, for example from electrolytic capacitors or batteries. Therefore, the granules are already contaminated with various pollutants. The risk of fires and explosions in shredder or sorting installations increases. The legislature attempts to counteract this by way of the permissible limit value concentrations for pollutants in waste from shredders continuously having to be reduced, which in turn leads to an increasing expenditure on sorting.

Typically employed methods, such as magnetic separation, eddy current separation, sensor sorting, various dry and wet separation methods, electrohydraulic comminution, manual sorting, start at a point at which the recycling capability has already been considerably reduced in an irretrievable manner. The technological or energetic complexity for increasing the recycling rate are already extremely high at this point. This shows that breaking down the products into their individual parts is preferable to shredding.

In developing countries to which old electrical devices are often exported nowadays, relevant recyclable and raw materials, such as copper and aluminum, are extracted from the defective devices by setting the devices on fire or by dissolving them in acid baths. Residual parts are often incinerated or deposited in landfill, this resulting in massive damage to humans and the environment.

The object of the invention is therefore to provide an electrical device and a method, which electrical device can be easily separated and broken down into individual parts without special tools or special knowledge.

This object is achieved according to the invention by the electrical device as claimed in claim 1. Advantageous refinements of the device according to the invention are specified in dependent claims 2 to 5. The object is likewise achieved according to the invention by the method for separating an electrical device as claimed in claim 6. Advantageous refinements of the method according to the invention are specified in dependent claims 7 to 12.

The electrical device as claimed in claim 1 comprises electronic components which are enclosed by a housing, wherein a marking for separating the electrical device is applied to the housing.

It is advantageous here that an efficient disassembly method, which leads to a higher recycling rate, is provided. Disassembly can be performed by trained personnel. No specialist knowledge about the design and function of the electrical devices to be disassembled is required. Simple marking with symbols in conjunction with the disassembly instructions provided by the manufacturers provides all the machine-related information. One advantage of the electrical device according to the invention is that a corresponding configuration can be used in a large number of electrical devices, irrespective of the manufacturer of the electrical device. Owing to the selected technological approach, tools are available which, upon closer analysis, actually make it possible for any electrical device to be disassembled. For example, milling machines can remove virtually any desired material, and saw blades or lasers also open large housing parts within fractions of a second. Existing electrical devices can be accommodated in a database at neutral cost, as it were “retrofitted”, and therefore can be disassembled from the installation after the end of the service life. The electrical device according to the invention can be used with few personnel at an extremely high disassembly rate.

In one refinement of the electrical device according to the invention, the marking on the housing is in the form of a QR code or the marking is transmitted wirelessly.

In a further refinement of the electrical device according to the invention, the marking at least contains instructions for disassembling the electrical device, information relating to the materials making up the electrical device and information relating to the license.

In one refinement of the electrical device, the marking contains information relating to the defined position on the housing of the electrical device. This information about the defined position can be contained in the QR code.

The method according to the invention for separating an electrical device according to the invention as claimed in claim 6 comprises the steps of:
identifying the electrical device and checking the license;
comparing this information with a database and loading the instructions for disassembling the electrical device; and
disassembling and sorting the electrical device by means of multidimensionally controlled uptake.

In one refinement of the method according to the invention, this method comprises the further step of:
monitoring the disassembly and charging a license fee.

In one refinement of the method according to the invention, the step:
identifying the electrical device and checking the license;
comprises the following steps:
reading the marking for separating the electrical device;
comparing the instructions for disassembling the electrical device, the information relating to the materials of the electrical device and the information relating to the license with the database.

In a further refinement of the method according to the invention, the step:
comparing this information with a database and loading the instructions for disassembling the electrical device;
comprises the following steps:
comparing the entry from the database;
loading the instructions for disassembling the electrical device;
loading the information relating to the materials; so that the process of disassembly is defined.

In a further refinement of the method according to the invention, the step:
disassembling and sorting the electrical device by means of multidimensionally controlled uptake;
comprises the following steps:
disassembling the electrical device, so that the electrical device is separated;
loading the information relating to the materials; and
sorting the materials into the containers provided for them; so that the sorting is completed.
The step:
monitoring the disassembly and charging a license fee; may comprise the following steps:
checking the status of the method; and
releasing a license payment.

In a further refinement of the method according to the invention, the method is carried out in an automated manner 27 by a CNC milling center with multidimensionally controlled and driven uptake.

The above-described properties, features and advantages of this invention, and the way in which they are achieved, will be more clearly and distinctly comprehensible in conjunction with the following description of the embodiments which are explained in more detail in conjunction with the figures,

in which:

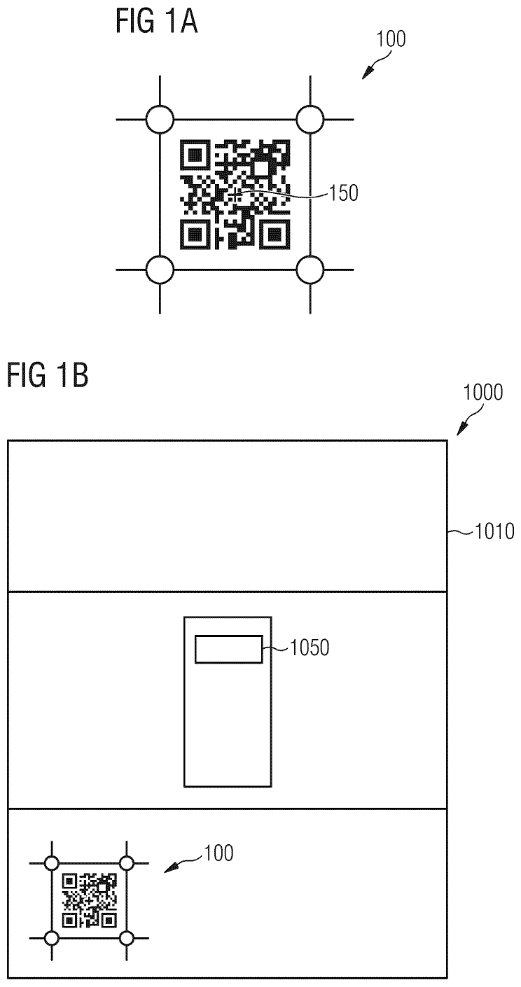

FIG. 1 shows a marking for separating an electrical device;

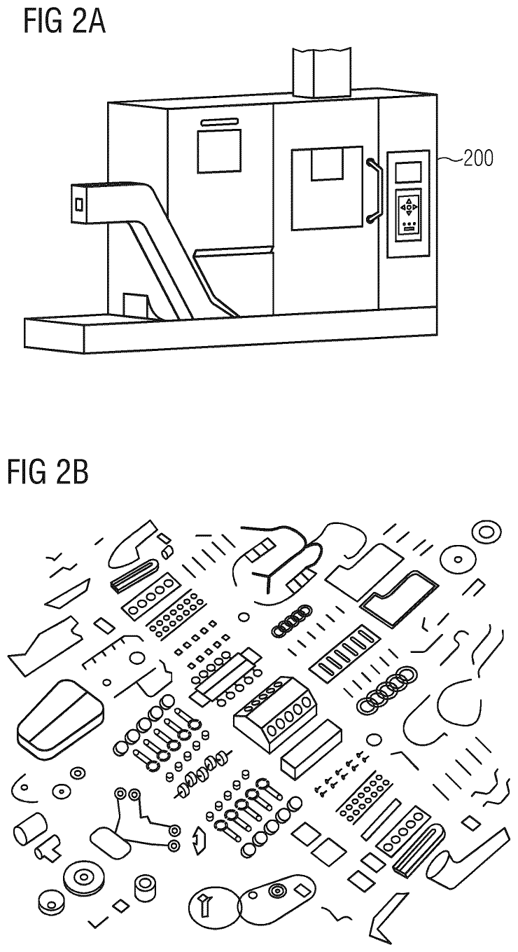

FIGS. 2A and 2B show a CNC milling center and a separated electrical device; and

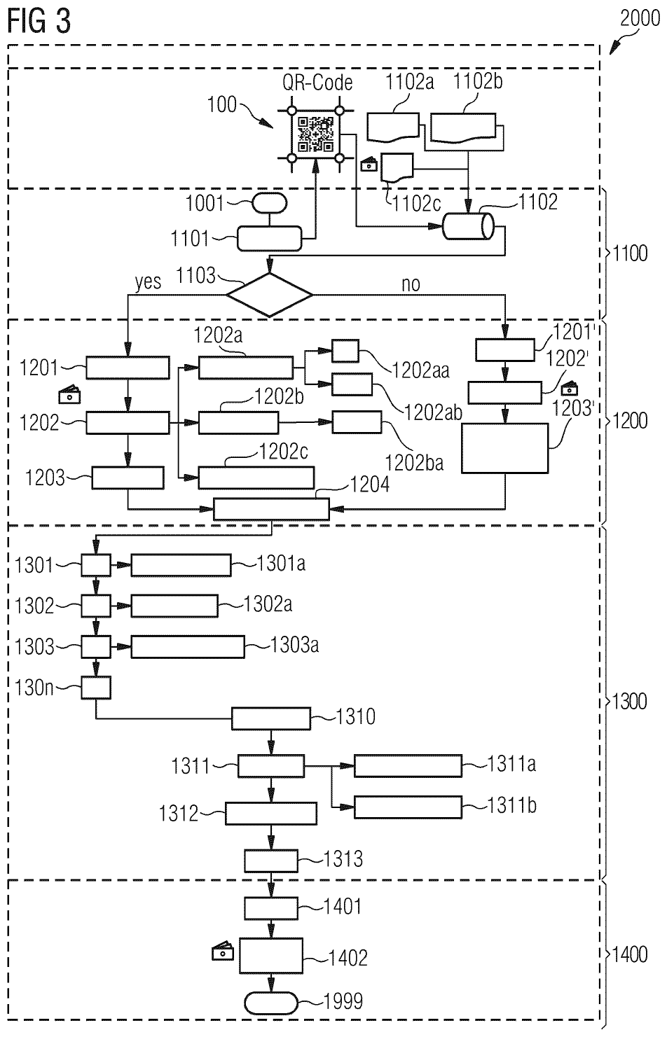

FIG. 3 shows a method according to the invention for separating an electrical device.

FIG. 1B shows an electrical device 1000 which is enclosed by a housing 1010. For example, the electrical device 1000 can be an electrical switch which can be manually switched by means of a handle 1050. Electronic components are situated in the interior of the electrical device 1000 and enclosed by the housing 1010.

A marking 100 is applied to the housing 1010 of the electrical device 1000 for separating the electrical device 1000.

In one embodiment, this marking 100 is a QR code, as is illustrated in FIG. 1A. This QR code is applied to the housing 1010. As an alternative, the marking 100 can also be transmitted wirelessly, for example by means of the NFC standard, by Bluetooth or by means of another wireless protocol.

The marking 100 at least contains instructions for disassembling the electrical device 1000, information relating to the materials making up the electrical device 1000 and information relating to a possible license.

The marking 100 can additionally contain information relating to the defined position 150 on the housing 1010 of the electrical device 1000. In the case of a QR code corresponding to FIGS. 1A and 1B, the information about the defined position 150 is contained in the QR code, for example in the form of a red cross.

The marking 100 can likewise comprise a reference to a database 1102 in which the instructions for disassembling the electrical device 1000, information relating to the materials making up the electrical device 1000 and information relating to a possible license are retrievably stored.

FIG. 3 shows the sequence of the method 2000 according to the invention for separating an electrical device 1000. The method 2000 runs between the start 1001 and the end 1999. The method 2000 according to the invention comprises the steps of:
identifying the electrical device 1000 and checking the license 1100;
comparing this information with a database 1102 and loading the instructions 1200 for disassembling the electrical device 1000; and
disassembling and sorting 1300 the electrical device 1000 by means of multidimensionally controlled uptake.

For example, disassembly and sorting 1300 of the electrical device 1000 can be carried out in an automated manner by a CNC milling center 200, which is shown in FIG. 2A. FIG. 2B shows the components of the electrical device 1000 after it has been broken down by the method 2000 according to the invention.

The step
identifying the electrical device 1000 and checking the license 1100;
after the start 1001 comprises the following steps:
reading 1101 the marking 100 for separating the electrical device 1000; and
comparing 1102 the instructions for disassembling 1102A the electrical device 1000, the information relating to the materials 1102B of the electrical device 1000 and the information relating to the license 1102C with the database 1102.

Once the license 1103 has been checked, if a license exists, the step
comparing this information with a database 1102 and loading the instructions 1200 for disassembling the electrical device 1000;
comprises the following steps:
comparing 1201 the entries from the database;
loading 1202 the instructions for disassembling the electrical device 1000; and
loading 1203 the information relating to the materials, so that the process of disassembly 1204 is defined.

As an alternative, if a license does not exist, manual configuration 1201′ can be carried out. In this case, a CAD model 1202′ can be configured and in a further step 1203′ manual elements such as rivets can be detected and corresponding instructions for the removal tool can be determined, so that the process of disassembly 1204 is defined.

The step
disassembling and sorting 1300 the electrical device 1000 by means of multidimensionally controlled uptake;
comprises the following steps:
disassembling 1301; 1302; 1303; . . . ; 130n the electrical device 1000, so that the electrical device 1000 is separated 1310;
loading 1311 the information relating to the materials; and
sorting 1312 the materials into the containers provided for them; so that the sorting 1313 is completed.

Loading 1311 of the information relating to the materials can be based on different components of the electrical device 1000, for example on the material of the housing 1311A and on the material of the contact arm 1311B and further materials.

The method 2000 according to the invention can be supplemented with the further step of:
monitoring the disassembly and charging a license fee 1400.
This step can be split into
checking 1401 the status of the method 2000; and
releasing 1402 a license payment.

Electrical devices 1000 can be separated and sorted by the universally applicable assembly and disassembly method 2000 in an economical manner. As a result, separation yielding unmixed recyclable materials or else reuse of components is achieved after the end of the service life, this in turn leading to an increase in the recycling rate.

The method 2000 according to the invention goes beyond the simple disassembly process; it additionally takes into account the sorting process as well. The method is universally applicable and therefore constitutes a solution approach for all electrical devices 1000 and further products.

For example, a QR code can be applied to electrical devices 1000, the QR code fulfilling the tasks of:
signals the recyclability of the electrical device 1000,
serves as a licensing symbol,
serves to uniquely identify the electrical device 1000, and
contains information relating to the defined position 150 on the housing 1010 as a reference zero point. This middle point can be used in conjunction with further markings or with a 3D model, which is stored in the database, for generating a digital image in the installation. The advantage when using the QR code in conjunction with a digital image is that a QR code suffices for clear positioning in space.

The QR code or the database 1102 have to provide the following information:
instructions for disassembling the electrical device 1000;
information relating to the materials making up the electrical device 1000; and
information relating to the license.

A camera system identifies the QR code and carries out a check on the license in the database 1102.

Comparison with the database 1102 leads to the following disassembly instructions:
identifying connecting elements in terms of type and position relative to the zero point;
selecting suitable disassembly tools;
initializing and referencing to the zero point; and
if the product is not found in the database 1102 and in spite of this disassembly should be possible, automatic detection of the type of product, comparable products, connecting elements and materials can take place, suitable disassembly tools may possibly be proposed, definition of a disassembly process can be proposed and monitoring by the operator and manual starting of disassembly can be carried out. These steps can also be assisted or carried out with the aid of artificial intelligence methods.

Disassembly is carried out with multidimensionally controlled and driven uptake in a multistage process which consists of a sequence of substeps. Separation means:
selecting and receiving the defined tool from the fitted tool store;
preconfiguring the drive, such as for example a milling device with a diameter of 5 mm, a milling depth of 10 mm and 1000 revolutions in the clockwise direction;
carrying out the disassembly steps;
transporting the tool back to the tool store.

The following procedure is followed for sorting:
loading the material information from the database 1102;
transporting and storing the parts in containers correspondingly provided for them; and
automated separating yielding unmixed products in the installation.

Disassembly can be subject to monitoring and a license fee can be charged:
automatic or manual monitoring of the disassembly,
charging of a license fee for licensed products;
possibility of optimizing the disassembly process by the operator;
possibility of optimizing the disassembly process by artificial intelligence methods by the acquisition of corresponding software modules; and
in the case of non-licensed products, there is the possibility of storing the configured disassembly process after a successful disassembly. As a result, structurally identical products are then automatically identified and can be broken down using the defined disassembly process at a later time. The prerequisite for this is also to acquire a corresponding software module.

For example, a CNC milling center 200 can be used when existing installations are used. A CNC milling center already has all the components required for operating such an installation. It would therefore be entirely conceivable to develop such a disassembly concept and method 2000 in cooperation with a large CNC milling center manufacturer. One advantage of this is that, when the method 2000 according to the invention is applied, no new installation type has to be developed, but rather existing CNC milling centers 200 or laser cells obtain an upgrade in terms of software and hardware and thus become multifunctional installations which can be used both for manufacture and also for disassembly.

1-12. (canceled)

13. An electrical device, comprising:
electronic components and a housing enclosing the electronic components;
a marking pertaining to a disassembly of the electrical device (1000) applied to the housing.

14. The electrical device according to claim 13, wherein the marking on the housing is a QR code or the marking is a wirelessly transmittable marking.

15. The electrical device according to claim 13, wherein the marking contains instructions for disassembling the electrical device, information relating to materials making up the electrical device, and information relating to a license.

16. The electrical device according to claim 13, wherein the marking contains information relating to a defined position on the housing of the electrical device.

17. The electrical device according to claim 16, wherein the information about the defined position is contained in a QR code of the marking.

18. A method for disassembling an electrical device, the electrical device having electronic components enclosed in a housing and a marking related to a disassembly of the electrical device applied to the housing, the method comprising:
identifying the electrical device and checking a license pertaining to the electrical device;
aligning information gained in the identifying step with a database and loading instructions for disassembling the electrical device; and
disassembling and sorting the electrical device by way of multidimensionally controlled uptake.

19. The method according to claim 18, which further comprises monitoring the disassembly of the electrical device and charging a license fee.

20. The method according to claim 18, wherein the step of identifying the electrical device and checking the license comprises the following:
reading the marking for the disassembly of the electrical device;
aligning the instructions for disassembling the electrical device, the information relating to materials of the electrical device, and information relating to the license with the database.

21. The method according to claim 18, wherein the step of aligning the information with the database and loading the instructions for disassembling the electrical device comprises the following:
aligning the entry from the database;
downloading the instructions for disassembling the electrical device;
downloading the instructions relating to the materials;
for defining the disassembly process.

22. The method according to claim 18, wherein the step of disassembling and sorting the electrical device by way of multidimensionally controlled uptake comprises the following:
disassembling the electrical device to separate the electrical device;
downloading information relating to the materials; and
sorting the materials into corresponding containers, to complete the sorting.

23. The method according to claim 19, wherein the step of monitoring the disassembly of the electrical device and charging a license fee comprises:
checking a status of the disassembly process; and
triggering a license payment.

24. The method according to claim 18, which comprises carrying out the method in an automated process by a CNC milling center with multidimensionally controlled and driven uptake.
